(19) United States
(12) Patent Application Publication
(10) Pub. No.: US 2013/0093459 A1
(43) Pub. Date: Apr. 18, 2013

(54) TERMINATION DEVICE SYSTEM

(71) Applicants: Chunyi LI, Shanghai (CN); Qingjiang MA, Shanghai (CN)

(72) Inventors: Chunyi LI, Shanghai (CN); Qingjiang MA, Shanghai (CN)

(73) Assignee: MONTAGE TECHNOLOGY (SHANGHAI) CO. LTD., Shanghai (CN)

(21) Appl. No.: 13/600,954

(22) Filed: Aug. 31, 2012

(30) Foreign Application Priority Data
Oct. 13, 2011 (CN) 201110310543.X

(51) Int. Cl. H03K 19/00

(52) U.S. Cl. CPC H03K 19/0005
USPC 326/30

(57) ABSTRACT

A termination device system is provided that includes a device required to be terminated with a resistor and a termination circuit. The termination circuit includes a termination resistor circuit and a judgment circuit connected to the termination resistor circuit. The termination resistor circuit includes at least one controlled termination unit. Each controlled termination unit includes a termination connecting end for connecting the device required to be terminated with a resistor, a controlled switch and a resistor, and provides, based on on/off of the controlled switch, a termination resistor for the device connected to the termination connecting end. The judgment circuit judges whether the device is required to be connected to the termination resistor based on a control instruction of a control device controlling the device connected to the termination connecting end, to output an on/off control signal to the controlled switch of the termination resistor circuit to control on/off.

### BACKGROUND OF THE PRESENT INVENTION

1. Field of Invention

The present invention relates to the field of circuit, and more particularly to a termination device system.

2. Description of Related Arts

When devices in the prior art, for example, a memory chip unit and a data buffer of a Double Data Rate (DDR) memory, required to be terminated with resistors are in use, termination resistors are often required. As shown in FIG. 1, a memory module includes multiple memory chips having left ends terminated with a resistor R1 and right ends terminated with a resistor R3, and data buffers having left ends terminated with a resistor R2 and right ends terminated with a resistor R4, The biggest problem of a memory module of the circuit structure is as follows. When the memory chip units and the data buffers are in an idle state, a control buffer still outputs a digital signal 1 or 0, which causes a termination resistor thereof to consume power, thereby wasting electrical energy. Therefore, it is urgent to improve the circuit structure.

### SUMMARY OF THE PRESENT INVENTION

An objective of the present invention is to provide a termination resistor circuit, so as to provide a termination resistor for a device required to be terminated with a resistor.

Another objective of the present invention is to provide a termination circuit,

Another objective of the present invention, is to provide a termination device system with low power consumption.

In order to achieve the above objectives and other objectives, the termination resistor circuit provided by the present invention includes at least one controlled termination unit, and each controlled termination unit includes a termination connecting end for connecting a device required to be terminated with a resistor, a controlled switch and a resistor. The device is used for providing a termination resistor for the device connected to the termination connecting end based on on/off of the controlled switch.

Preferably, the at least one controlled termination unit includes a voltage divider resistor circuit for performing voltage division on a power supply voltage, wherein the voltage divider resistor circuit includes resistors and controlled switches.

Preferably, the termination resistor circuit is a termination chip, and each controlled termination unit is within the termination chip, alternatively, the termination resistor circuit includes a termination chip, and in the at least one controlled termination unit, the circuit part, except the resistor, is within the termination chip.

Preferably, the device required to be terminated with a resistor includes a memory chip unit and/or a data butler.

The termination circuit provided by the present invention includes the termination resistor circuit and a judgment circuit. The judgment circuit has an output end connected to the termination resistor circuit, and is for judging whether the device connected to the termination connecting end is required to be terminated with a resistor based on a control instruction of a control device controlling the device connected to the termination connecting end, so as to output an on/off control signal to the termination resistor circuit to control on/off of the controlled switch of the termination resistor circuit

Preferably, when the device connected to the termination connecting end includes a memory chip unit and/or a data buffer, the judgment circuit is disposed in a control buffer connected to the memory chip unit.

The termination device system provided by the present invention includes a device. required to be terminated with a resistor and the termination circuit.

Preferably, when the device required to be terminated with a resistor includes at least one memory chip unit and/or data butler and the judgment circuit is disposed in a control buffer connected to the memory chip unit, the device to be terminated and the termination circuit are members in a memory module.

In view of the above, advantages of the present invention are as follows. A termination resistor may be provided only based on needs of a device required to be terminated with a resistor, so as to solve the problem in the prior art that when the device required to be terminated with a resistor is in an idle state, a resistor terminating the device still consumes power, thereby effectively reducing power consumption and saving energy,

### BRIEF DESCRIPTION OF THE DRAWINGS

FIG. 1 is a schematic structural view of a memory module in the prior art.

FIG. 2 is a schematic structural view of a termination device system of the present invention

FIG. 3 is a schematic view of a preferred termination circuit of the present invention.

FIG. 4 is a schematic view of a controlled, termination unit included in a termination circuit of the present invention.

FIG. 5 is a schematic view of a circuit structure of a preferred controlled termination unit of the present invention.

FIG. 6 is a schematic view of a preferred termination circuit formed based on the controlled termination unit shown in FIG. 5.

FIG. 7 is a schematic view of another preferred termination circuit formed based on the controlled termination unit shown in FIG. 5.

FIG. 8 is a schematic view of a circuit structure of another preferred controlled termination unit of the present invention.

FIG. 9 is a schematic view of a preferred termination circuit formed based on the controlled termination unit shown in FIG. 8.

FIG. 10 is a schematic view of a preferred memory module of the present invention.

FIG. 11 is a schematic view of another preferred memory module of the present invention,

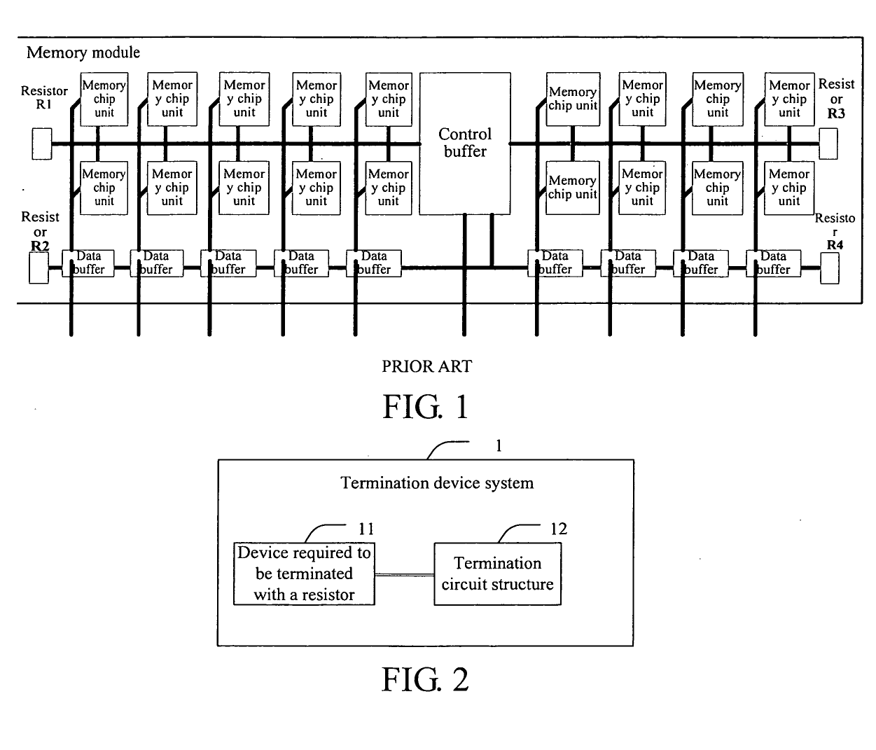

### DETAILED DESCRIPTION OF THE PREFERRED EMBODIMENTS

Referring to FIG. 2, a termination device system 1 of the present invention includes a device 11 required to be terminated with a resistor and a termination circuit 12.

The device 11 required to be terminated with a resistor may be any component which is required to be terminated with a resistor when working, and preferably, may be, but not limited to, a memory chip unit and a data buffer, for example, a memory chip unit and/or a data buffer in a Registered Dual in-line Memory Module (RDIMM) or a Load Reduced Dual In-line Memory Module (LRDIMM).

The termination circuit 12 may be any circuit which may provide a termination resistor for the device 11 required to be terminated with a resistor when the device 11 required to be terminated with a resistor is working and does not provide any termination resistor for the device 11 required to be terminated with a resistor when the device 11 required to be terminated with a resistor is idle

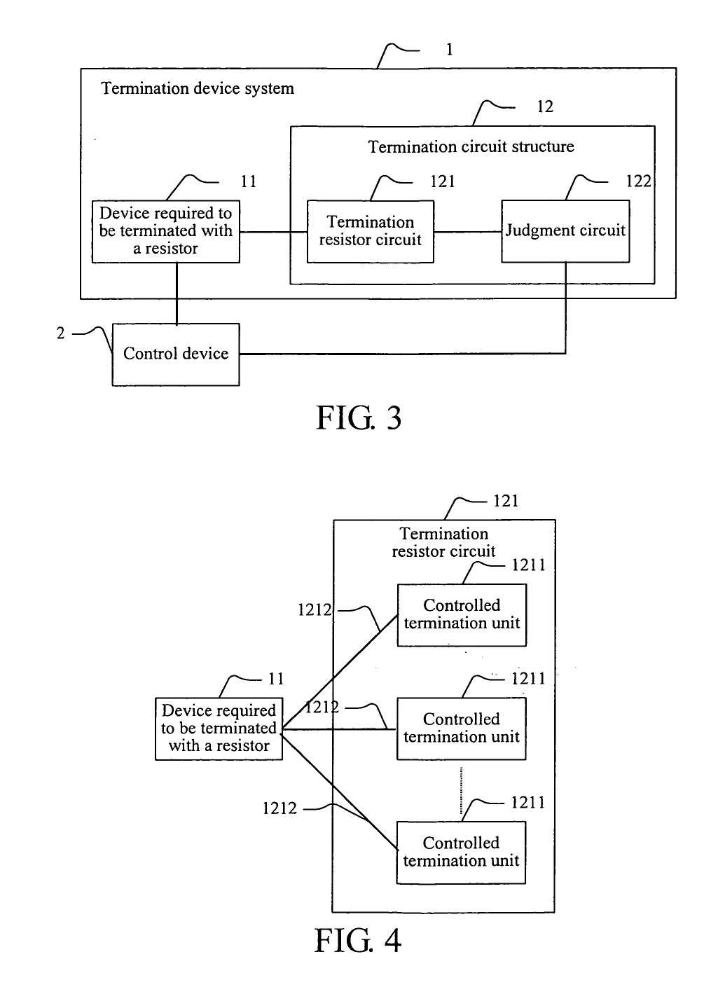

Preferably, the termination circuit 12 includes a termination resistor circuit 121 and a judgment circuit 122, as shown in FIG. 3.

The termination resistor circuit 121 includes at least one controlled termination unit 1211, as shown in FIG. 4. Each controlled termination unit 1211 includes a termination connecting end 1212 for connecting the device 11 required to be terminated with a resistor, a controlled switch (not shown) and a resistor (not shown), and is for providing, based on on/off of the controlled switch, a termination resistor for the device 11 required to be terminated with a resistor and connected to the termination connecting end 1212.

It should be noted that, persons skilled in the art should understand that although the termination resistor circuit in FIG. 4 includes multiple controlled termination units, in fact the termination resistor circuit may include only one controlled termination unit.

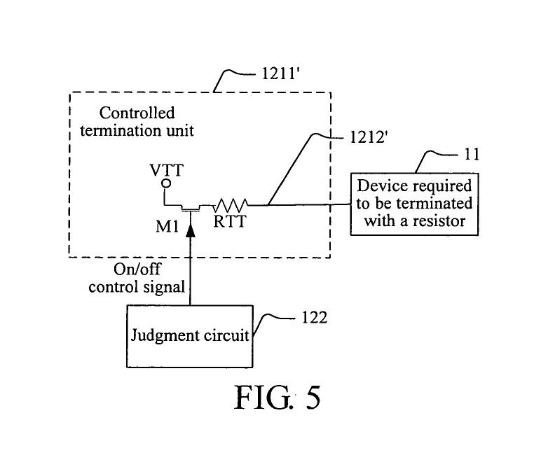

FIG. 5 is a schematic view of a preferred circuit of the controlled termination unit. A controlled termination unit 1211′ includes a controlled switch M1 and a resistor RTT connected to one terminal of the controlled switch M1. A controlled terminal of the controlled switch M1 is connected to an on/off control signal from the judgment circuit 122, and the other terminal is connected to a voltage VTT. The other end of the termination resistor RTT is a termination connecting end 1212 connected to the device 11 required to be terminated with a resistor,

It should be noted that, persons skilled in the art should understand that the controlled switch M1 may be implemented by employing a crystal triode or a field effect transistor.

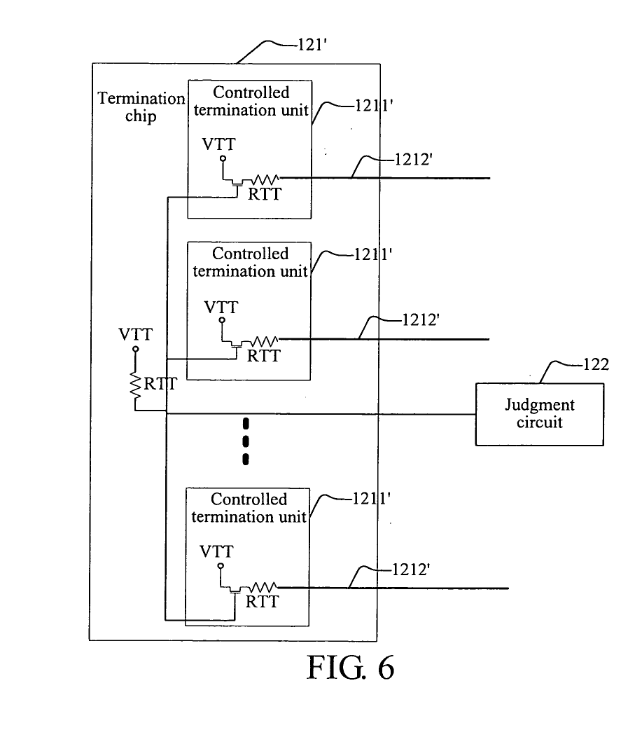

A preferred circuit structure of the termination resistor circuit formed based on the at least one controlled termination unit 1211′ is as shown in FIG. 6, in which the controlled termination unit 1211′ included in the termination resistor circuit constitutes a termination chip 121′, that is, each controlled termination unit 1211′ is within the termination chip 121′.

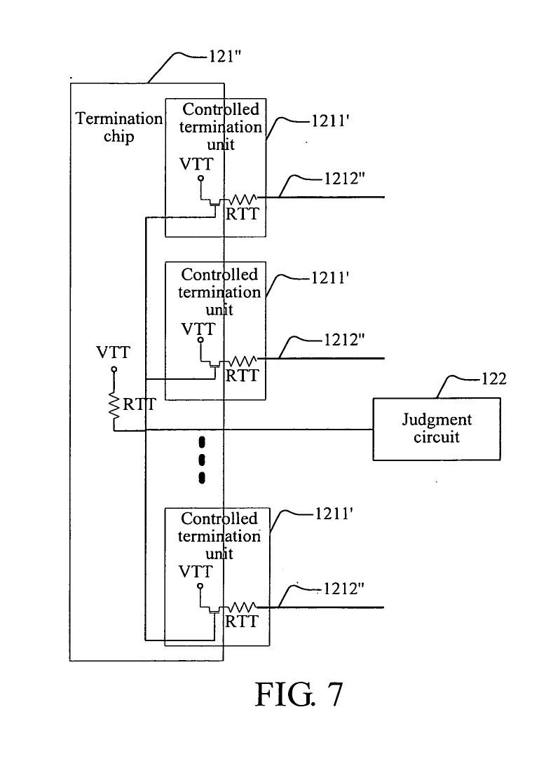

Further, another preferred circuit structure of the termination resistor circuit formed based on the at least one controlled termination unit 1211′ is as shown in FIG. 7, in which the termination resistor circuit includes a termination chip 121″ and resistors RTT connected to the termination chip 121″, One end of each resistor RTT is a termination connecting end 1212″, and as shown in the FIG. 7, the circuit part of each controlled termination unit 1211′, except the resistor RTT, is within the termination chip 121″.

It should be noted that, persons skilled, in the art should understand that the termination resistor circuit formed based on the controlled termination unit 1211′ is not limited by the above description, and in fact in the termination resistor circuit formed based on the controlled termination unit 1211′, the resistors included in a part of the controlled termination units 1211′ may be within the termination chip and the resistors included in a part of the controlled termination units 1211′ may be out of the termination chip.

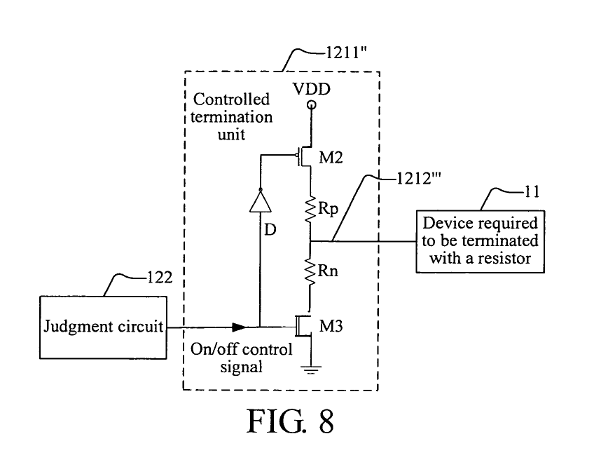

FIG. 8 is a schematic view of another preferred circuit of the controlled termination unit. A controlled termination unit 1211″ includes a voltage divider resistor circuit for performing voltage division on a power supply voltage, The voltage divider resistor circuit includes resistors Rp, Rn, controlled switches M2, M3, and a phase inverter D. A common connection end of the resistors Rp, Rn is a termination connecting end 1212′ connected to the device 11 required to be terminated with a resistor. A controlled terminal of the controlled switch M3 is connected to the judgment circuit 122. The controlled switch M2 has a controlled terminal connected to the judgment circuit 122 through the phase inverter D, and one terminal connected to a power supply voltage VDD.

It should be noted that, persons skilled in the art should understand that the controlled switch M2, M3 may be implemented by employing crystal triodes or field effect, transistors.

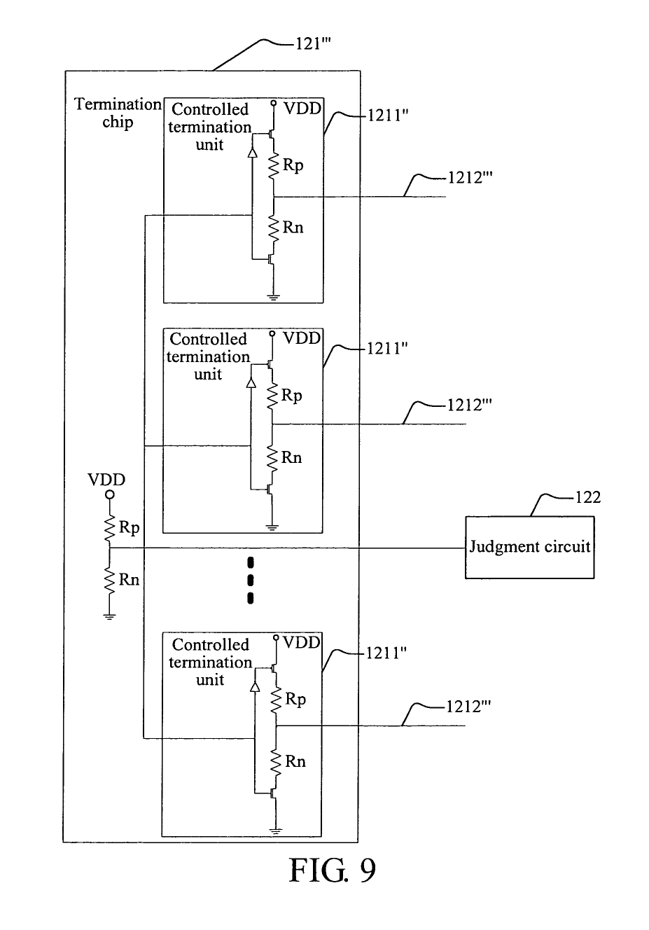

A preferred schematic view of the termination resistor circuit formed based on the at least one controlled termination unit 1211″ is as shown in FIG. 9, in which the controlled termination unit 1211″ included in the termination resistor circuit constitutes a termination chip 121′″, that is, each controlled termination unit 1211″ is within the termination chip 121′″.

It should be noted that, persons skilled in the art should understand that the termination resistor circuit formed based on the controlled termination unit 1211″ is not limited by the above description, and in fact in the termination resistor circuit formed based on the controlled termination unit 1211″, all of the resistors included in each controlled termination unit 1211″ may be out of the termination chip; or the resistors included in a part of the controlled termination units 1211″ may be within the termination chip and the resistors included in a part of the controlled termination units 1211″ may be out of the termination chip.

Further, it should be noted that persons skilled in the all should understand that the circuit structure of the controlled termination unit shown above is only for illustration, but not intended to limit the present invention. In fact, the controlled termination unit may be implemented by employing other circuit structures.

The judgment circuit 122 is for judging whether the device 11 required to be terminated with a resistor is required to be terminated with a resistor based on a control instruction of a control device 2 controlling the device 11 connected to the termination connecting end, so as to output an on/off control signal to the termination resistor circuit 121 to control on/off of the controlled switch of the termination resistor circuit 121.

Preferably, when the device 11 required to be terminated with a resistor includes a memory chip unit and/or a data buffer, the judgment circuit 122 is disposed in a control buffer connected to the memory chip unit.

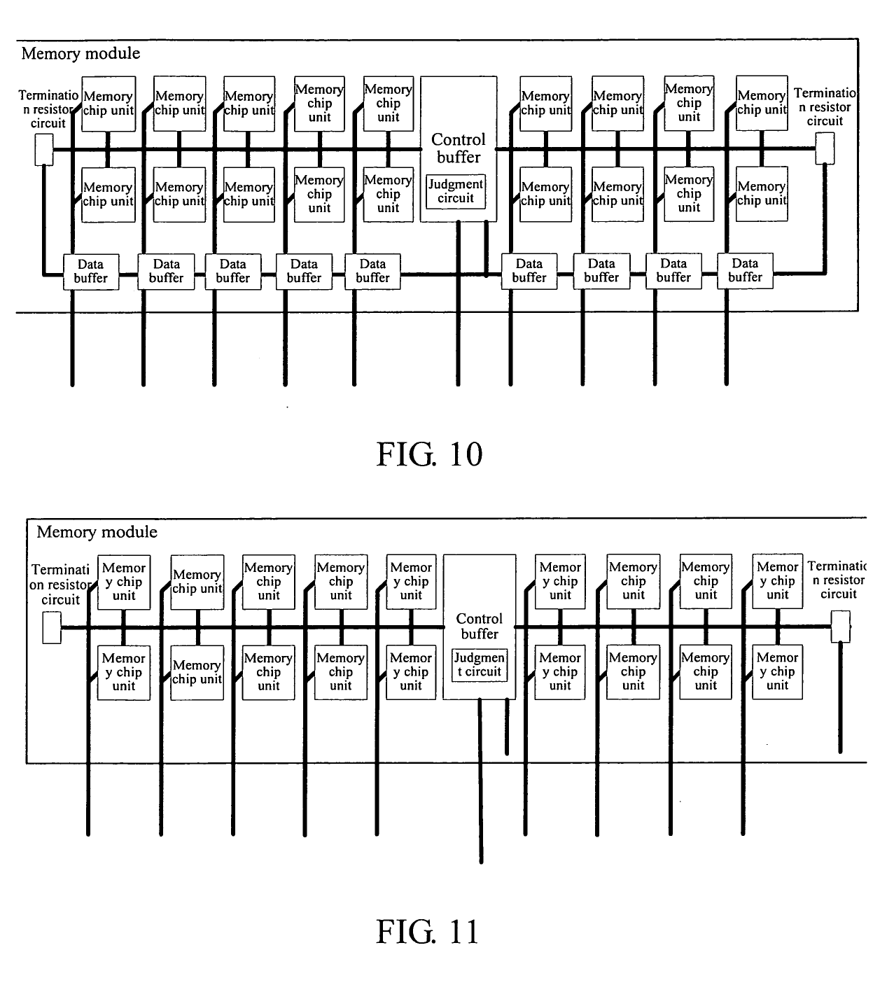

FIG. 10 is a schematic view of a preferred memory module including a judgment circuit, termination resistor circuits, memory chip units, data buffers and a control butter. The judgment circuit is disposed in the control buffer, and in order to simply the illustration connecting lines between the judgment circuit and the left termination resistor circuit/right termination resistor circuit are not shown. The left termination resistor circuit and right termination resistor circuit of the memory module may be any termination resistor circuit described above, for example, the termination chip 121′ shown in FIG. 6, the termination resistor circuit, shown in FIG. 7, including the termination chip 121″, or the termination chip 121′″ shown in FIG. 9. Therefore, based on a command, an address or a control signal received by the control buffer thereof, the judgment circuit judges whether the memory chip unit and the data buffer in the memory module are required to be connected to a termination resistor.

FIG. 11 is a schematic view of a preferred memory module including a judgment circuit, termination resistor circuits, memory chip units and a control buffer. The judgment circuit is disposed in the control buffer, and in order to simply the illustration connecting lines between the judgment circuit and the left termination resistor circuit/right termination resistor circuit are not shown. The left termination resistor circuit and right termination resistor circuit of the memory module may be any termination resistor circuit described above, for example, the termination chip 121′ shown in FIG. 6, the termination resistor circuit, shown in FIG. 7, including the termination chip or the termination chip 121′″ shown in FIG. 9, Therefore, based on a command, an address or a control signal received by the control buffer thereof, the judgment circuit judges whether the memory chip unit in the memory module is required to be connected to a termination resistor:

An example is provided below to illustrate a working process of the judgment circuit 122.

For example, when the device 11 required to be terminated with a resistor includes a memory chip unit and a data buffer in a Double Data Rate 4 Load Reduced Dual In-line Memory Module (DDR4 LRDIMM), the judgment circuit is disposed in a control buffer in the DDR4 LRDIMM. A command, an address and a control signal received by the control buffer include: A[17:0], BG[1:0], BA[1:0], ACT_n, C[2:0], CS[n:0], CKE[1:0], ODT[1:0] and PAR, where n in CS[n:0] may be 1 or 3.

1. When detecting that CKE[1:0] and ODT[1:0] undergo transition, the judgment circuit judges that the device 11 required to be terminated with a resistor is required to be terminated with a resistor, and outputs an on/off control signal for switching on the controlled switch When detecting that both CKE[1:0] and ODT[1:0] undergo no transition, and CKE[1:0] is equal to 0, the judgment circuit judges that the device 11 required to be terminated with a resistor is not required to be terminated with a resistor, and outputs an on/off control signal for switching off the controlled switch.

2. When detecting that CKE and ODT do not undergo transition and further detecting that one signal in CS[n:0] is 0, the judgment circuit judges that the device 11 required to be terminated with a resistor is required to be terminated with a resistor, and outputs an on/off control signal for switching on the controlled switch. When detecting that CKE and ODT do not undergo transition and further detecting that all signals in CS[n:0] are 1, the judgment circuit judges that the device Ii required to be terminated with a resistor is not required to be terminated with a resistor, and outputs an on /off control signal for switching off the controlled switch.

It should be noted that, persons skilled in the art should understand that a specific circuit structure to be employed by the judgment circuit is based on a specific function the judgment circuit is required to perform. For example, when whether the device required to be terminated with a resistor is required to be terminated with a resistor is judged based on a command, an address or a control signal received by the control buffer, the judgment circuit may be realized by employing a comparison circuit or a combinational logic circuit. Further, it should be noted that when the termination resistor circuit in the memory module shown in FIG. 10 is the termination chip UV shown in FIG. 6 or the termination resistor circuit, shown in FIG. 7, including the termination chip 121″, the voltage VTT connected to the termination resistor circuit may obtained by transforming the power supply voltage VDD connected to the memory module, when the termination resistor circuit in the memory module shown in FIG. 10 is the termination chip 121″ shown in FIG. 9, the power supply voltage connected to the termination resistor circuit is the power supply voltage VDD connected to the memory module. Further, it should be understood by persons skilled in the art that the data buffer and the memory chip in the memory module shown in FIG. 10 are connected to one or more controlled termination units in the termination resistor circuit respectively.

A working process of the termination device system 1 is as follows.

The judgment circuit 122 judges whether the device 11 required to be terminated with a resistor is required to be terminated with a resistor based on a control signal of the control device 2 (for example the control buffer); if yes, the judgment circuit 122 outputs an on/off control signal for switching on the controlled switch to the termination resistor circuit 121, so that the controlled switch (for example, the controlled switch M1 or the controlled switches M2 and M3) included in the termination resistor circuit 121 is switched on, and therefore the termination resistor included in the termination resistor circuit 121 is in electrical communication with the device 11 to be terminated, and the device 11 required to be terminated with a resistor enters a normal working state. When the judgment circuit 122 judges that the device 11 required to be terminated with a resistor is not required to be terminated with a resistor based on a control signal of the control device 2 (for example the control buffer), the judgment circuit 122 outputs an on/off control signal for switching off the controlled switch to the termination resistor circuit 121, so that the controlled switch (for example, the controlled switch Ml or the controlled switches M2 and M3) included in the termination resistor circuit 121 is switched off, and therefore the termination resistor included in the termination resistor circuit 121 is no more in electrical communication with the device 11 to be terminated, and the device 11 required to be terminated with a resistor enters an idle state. At the moment, the resistor terminating the device 11 required to be terminated with a resistor does not have any current thereon, so that the resistor terminating the device 11 required to be terminated with a resistor does not consume any power.

In view of the above, in the termination device system of the present invention, whether the termination resistor circuit is in electrical communication with the device required to be terminated with a resistor is controlled based on the on/off control signal output by the judgment circuit. Therefore, when the device required to be terminated with a resistor is in the idle state, the termination resistor thereof consumes no power, thereby effectively reducing power consumption of the termination device system. Especially when the termination resistor circuit shown in FIG. 6 or FIG. 7 is employed, and when the device required to be terminated with a resistor is in the normal working state, among the multiple controlled termination units included in the termination resistor circuit, if the number of the controlled termination units receiving the signal “1” and the number of the controlled termination units receiving the signal “0” are the same at, the same time, no current passes through the termination connecting ends. Therefore, compared with the prior art, the current of the device, which is required to be terminated with a resistor, working normally, and connected to the termination connecting ends, decreases dramatically, thereby decreasing power consumption of the device, which is required to be terminated with a resistor and in working, further decreasing the power consumption of the termination device system, and effectively saving the energy.

The above description of the embodiments is only to illustrate the principles and effects of the present invention, and is not intended, to limit the present invention Any person skilled in the art may modify the embodiments without departing from the spirit and scope of the present invention. Therefore, the protection scope of the present invention is defined by the claims

1. A termination resistor circuit, comprising:
at least one controlled termination unit, each of which comprising a termination connecting end for connecting a device required to be terminated with a resistor, a controlled switch and a resistor, for providing a termination resistor for the device connected to the termination connecting end based on on/off of the controlled switch.

2. The termination resistor circuit as in claim 1, wherein the at least one controlled termination unit comprises a voltage divider resistor circuit for performing voltage division on a power supply voltage, wherein the voltage divider resistor circuit comprises resistors and controlled switches.

3. The termination resistor circuit as in claim 1, wherein the termination resistor circuit is a termination chip, and each controlled termination unit is within the termination chip.

4. The termination resistor circuit as in claim 1, wherein the termination resistor circuit comprises a termination chip, and in the at least one controlled termination unit, the circuit part, except the resistor, is within the termination chip.

5. The termination resistor circuit as in claim 1, wherein the device required to be terminated with a resistor comprises a memory chip unit and/or a data buffer.

6. A termination circuit, comprising: a termination resistor circuit and a judgment circuit connected to the termination resistor circuit, wherein
the termination resistor circuit comprises at least one controlled termination unit, and each controlled termination unit comprises a termination connecting end for connecting a device required to be terminated with a resistor, a controlled switch and a resistor, and is for providing, based on on/off of the controlled switch, a termination resistor for the device connected to the termination connecting end; and
the judgment circuit is for judging whether the device connected to the termination connecting end is required to be terminated with a resistor based on a control instruction of a control device controlling the device connected to the termination connecting end, so as to output an on/off control signal to the termination resistor circuit to control on/off of the controlled switch of the termination resistor circuit.

7. The termination circuit as in claim 6, wherein the at least one controlled termination unit comprises a voltage divider resistor circuit for performing voltage division on a power supply voltage, wherein the voltage divider resistor circuit comprises resistors and controlled switches.

8. The termination circuit as in claim 6 wherein the termination resistor circuit is a termination chip, and each controlled termination unit is within the termination chip.

9. The termination circuit as in claim 6, wherein the termination resistor circuit comprises a termination chip, and in the at least one controlled termination unit, the circuit part, except the resistor, is within the termination chip.

10. The termination circuit as in claim 8, wherein the device connected to the termination connecting end comprises a memory chip unit and/or a data buffer.

11. The termination circuit as in claim 10, wherein the judgment circuit is disposed in a control buffer connected to the memory chip unit.

12. A termination device system, comprising a device required to be terminated with a resistor and a termination circuit, wherein the termination circuit comprises a termination resistor circuit and a judgment circuit connected to the termination resistor circuit,
the termination resistor circuit comprises at least one controlled termination unit, and each controlled termination unit comprises a termination connecting end for connecting the device required to be terminated with a resistor, a controlled switch and a resistor, and is for providing, based on on/off of the controlled switch, a termination resistor for the device connected to the termination connecting end; and
the judgment circuit is for judging whether the device connected to the termination connecting end is required to be terminated with a resistor based on a control instruction of a control device controlling the device connected to the termination connecting end, so as to output an on/off control signal to the termination resistor circuit to control on/off of the controlled switch of the termination resistor circuit.

13. The termination device system as in claim 12, wherein when the device connected to the termination connecting end comprises at least one memory chip unit and/or data buffer and the judgment circuit is disposed in a control buffer connected to the memory chip unit, the device required to be terminated with a resistor and the termination circuit are members in a memory module.

14. The termination resistor circuit as in claim 2, wherein the termination resistor circuit is a termination chip, and each controlled termination unit is within the termination chip.

15. The termination resistor circuit as in claim 2, wherein the termination resistor circuit comprises a termination chip, and in the at least one controlled termination unit, the circuit part, except the resistor, is within the termination chip.

16. The termination circuit as in claim 7, wherein the termination resistor circuit is a termination chip, and each controlled termination unit is within the termination chip.

17. The termination circuit as in claim 7, wherein the termination resistor circuit comprises a termination chip, and in the at least one controlled termination unit, the circuit part, except the resistor, is within the termination chip.
